(19) United States
(12) Patent Application Publication
(10) Pub. No.: US 2009/0040082 A1
(43) Pub. Date: Feb. 12, 2009

(54) DEVICE FOR PROCESSING BINARY DATA WITH SERIAL/PARALLEL CONVERSION

(76) Inventors: Torsten Hinz, Munich (DE); Otto Schumacher, Dachau (DE); Patrick Runkel, Neubiberg (DE); Russell Homer, Los Gatos, CA (US)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/179,286

(22) Filed: Jul. 24, 2008

(30) Foreign Application Priority Data
Jul. 26, 2007 (DE) 102007035018.1-31

(51) Int. Cl. H03M 9/00

(52) U.S. Cl. 341/100

(57) ABSTRACT

A device for processing binary data comprises at least one transmission link having an input for receiving a serial bit stream and an output for forwarding bits in a parallel format, and a serial/parallel converter providing n≧2 successive data bits of the serial bit stream as n-bit data words in the parallel format. The serial/parallel converter comprises a 1-to-n demultiplexer which is constructed and controllable in such a manner that the successive data bits of the serial bit stream appear in succession at intervals equal to a bit period T_{B} cyclically at n data outputs and remain latched at the respective data output until a data bit appears again at the relevant data output and a relatching circuit with latching elements which receive the signals from the data outputs of the demultiplexer at which the first k data bits of each cycle appear and which are enabled in each case at a time which is between the beginning of the latching of the last data bit and the end of the latching of the first data bit of the relevant cycle in the demultiplexer, wherein 1≦k<n.

### CROSS-REFERENCE TO RELATED APPLICATIONS

This application claims foreign priority benefits under 35 U.S.C. § 119 to co-pending German patent application number DE 10 2007 035 018.1-31, filed 26 Jul. 2007. This related patent application is herein incorporated by reference in its entirety.

### BACKGROUND OF THE INVENTION

### Field of the Invention

The invention generally relates to devices for processing binary data, and more particularly, converting serial data bit streams into a parallel format.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows the construction of the demultiplexer and the relatching circuit in a transmission link between a data source and a data sink, according to one embodiment of the invention.

FIG. 2 shows a timing diagram of signals which occur at various points in the circuits shown in FIG. 1, according to one embodiment of the invention.

FIG. 3 shows the construction of a buffer circuit contained in the transmission link, according to one embodiment of the invention.

FIG. 4 shows a timing diagram of the signals occurring at various points in the buffer circuit according to FIG. 3, according to one embodiment of the invention.

FIG. 5 shows the construction of an adjustable delay circuit contained in the transmission link, according to one embodiment of the invention.

FIG. 6 shows the combination of a number of transmission links for data transmission between a number of outputs of a data source and respective associated data sinks, according to one embodiment of the invention.

FIG. 7 shows the scheme of an arrangement for data transmission between a number of outputs of a data source and respective associated data sinks within each module of a multiplicity of modules, according to one embodiment of the invention.

FIG. 8 shows the construction of a circuit for regenerating the serial bit stream in individual transmission links of the arrangement according to FIG. 7, according to one embodiment of the invention.

### DETAILED DESCRIPTION OF THE PREFERRED EMBODIMENT

Embodiments of the present invention relate to a device for processing binary data, comprising at least one transmission link which or each of which is arranged between a data source and an individually allocated data sink in order to convert a serial data bit stream, supplied by the source, into a sequence of n-bit data words in parallel format and to supply this sequence to the data sink.

Embodiments of the invention provide a transmission of data which are supplied as serial bit streams with a very high data rate (i.e. in the range of one or more Gigabits/second) by a memory controller, to a storage medium, e.g. to an integrated or DRAM chip or to storage modules which in each case contain a number of such chips.

A transmission link between data source, e.g. a controller and data sink, e.g. a DRAM, may exhibit a low latency. In other words, the time between the reception of the serial data at the input of the link and the arrival of the data as serial/parallel converted data words at the data sink should be short.

According to an embodiment, a device for processing binary data comprises at least one transmission link having an input for receiving a serial bit stream and an output for forwarding bits in a parallel format, and

a serial/parallel converter providing n≧2 successive data bits of the serial bit stream as n-bit data words in the parallel format. The serial/parallel converter comprises a 1-to-n demultiplexer which is constructed and controllable in such a manner that the successive data bits of the serial bit stream appear in succession at intervals equal to a bit period T_{B} cyclically at n data outputs and remain latched at the respective data output until a data bit appears again at the relevant data output and a relatching circuit with latching elements which receive the signals from the data outputs of the demultiplexer at which the first k data bits of each cycle appear and which are enabled in each case at a time which is between the beginning of the latching of the last data bit and the end of the latching of the first data bit of the relevant cycle in the demultiplexer, wherein 1≦k<n.

According to a further embodiment, a device for processing binary data comprising at least one transmission link. The transmission link comprises a serial/parallel converter converting n≧2 successive data bits of a serial bit stream as n-bit data words in the parallel format as frames and a buffer circuit. The buffer circuit comprises a FIFO register and receives at its input the frames of the serial/parallel converter, wherein a write pointer of the buffer circuit is controlled by a first frame clock and a read pointer of the buffer circuit is controlled by a second frame clock, and wherein the FIFO register is bridged by a bypass when the read pointer and the write pointer come close to one another.

According to a further embodiment, a device for processing binary data comprises at least one transmission link having an input for receiving a serial bit stream and an output for forwarding bits in a parallel format and a serial/parallel converter converting n≧2 successive data bits of a serial bit stream as n-bit data words in the parallel format as frames. The transmission link further comprises a delay device, the delay time of which can be varied in increments of in each case one frame period T_{F}.

According to a further embodiment, a device for processing binary data comprises at least two transmission links. Each transmission link has an input for receiving a serial bit stream and an output for forwarding bits in a parallel format and a serial/parallel converter converting n≧2 successive data bits of a serial bit stream as n-bit data words in the parallel format as frames. Further each transmission link is arranged between an individually allocated output of a data source and an individually allocated data sink, wherein the clock signal for the clock control of the data reception at all data sinks is a common clock signal.

In the figures and in the subsequent description, identical and similar elements are in each case designated by the same reference symbols, in most cases together with a following alphanumeric signal (decimal number or small letter) which specifies a sequence number for the more detailed identification of the relevant element, the symbol “i” denoting an arbitrary sequence number. A colon “:” between two numbers is in each case to be read as the word “to”. Depending on context, the “ . . . ” symbol can be read as “to” or “and following”.

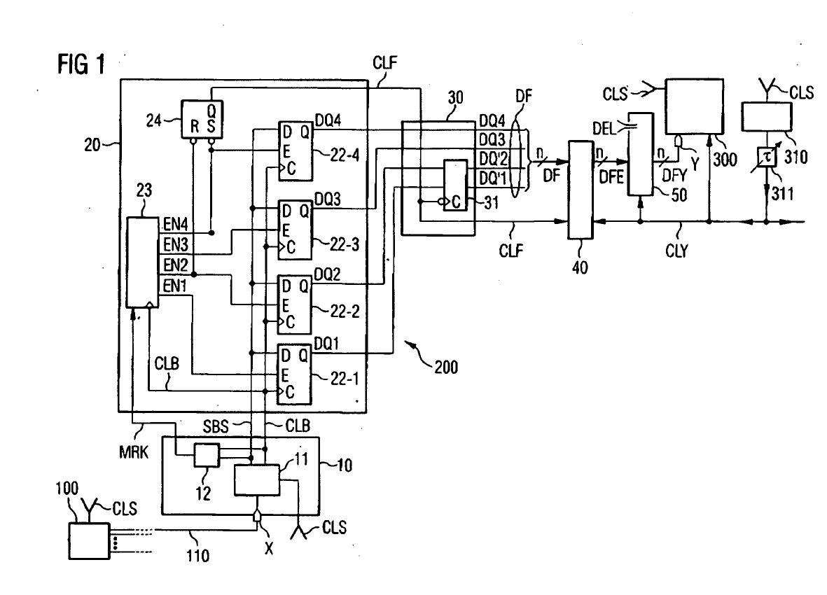

In FIG. 1, a data source which supplies a serial bit stream via an output data line 110 to an input X of a transmission link 200, the output Y of which is connected to the data input of a data sink 300, is shown as a block 100 at the bottom left, according to one embodiment of the invention. The bit stream supplied via the data link 110 may consist of individual data bits which follow one another with the period T_{B} (bit period), the timing of the data sampling in the data source 100 being controlled by a system clock signal CLS of frequency f_{B}=1/T_{B}.

The transmission link may ensure that successive sections (frames) of in each case n bits of the serial bit stream are applied to the n-bit parallel input of the data sink 300 as successive n-bit words in parallel format, in accordance with a frame clock, the period (frame period) of which is equal to n-times the bit period T_{B} of the serial bit stream. That is to say, the frame clock has the frequency f_{F}=1/(n*T_{B}).

Thus, a serial/parallel conversion may take place in the transmission link 200. In one embodiment, the transmission link may contain a 1-to-n demultiplexer 20 which samples the n successive data bits of each frame of the serial bit stream by means of active edges of an input clock signal CLB and provides n associated output lines of the demultiplexer 20.

The transit time of the bit stream from the source 100 to the input X of the transmission link 200 may be dependent on the physical characteristics of the data line 110. The length, the specific electrical parameters and also the type of installation of the line contribute to these characteristics, as do the respective environmental influences. Since the complex of all line characteristics, and thus also the transit time, cannot be accurately predicted and can also fluctuate within a certain tolerance range during operation, an input circuit 10 may be connected ahead of the demultiplexer 20. As shown, the circuit 10 (a so-called data clock recovery circuit) contains a phase locked loop 11 which receives the input bit stream CBS and the system clock signal CLS and generates at its output the input clock signal CLB and the serial bit stream SBS relative to one another with a phase relationship which is suitable for a reliable sampling of the data bits of the serial bit stream.

The actual serial/parallel conversion in the demultiplexer 20 may be effected by means of a group of n latch elements 22-1, 22-2 . . . 22-n and a write control circuit 23. Each of the latch elements may in each case be allocated to one of the n bits of each frame. In FIG. 1, the demultiplexer 20 is shown for the example of n=4, that is to say containing four latch elements 22-1, 22-2, 22-3, 22-4. Each latch element 22-i has a data input D for receiving the serial bit stream SBS, a clock input C for receiving the input clock signal CLB and an enable input E for receiving an associated enable pulse ENi from an associated output of the write control circuit 23. Each latch element 22-i is constructed in such a manner that a data bit present at its data input D appears latched at its data output Q as soon as an active edge of the input clock signal CLB appears when an associated enable pulse ENi is simultaneously present.

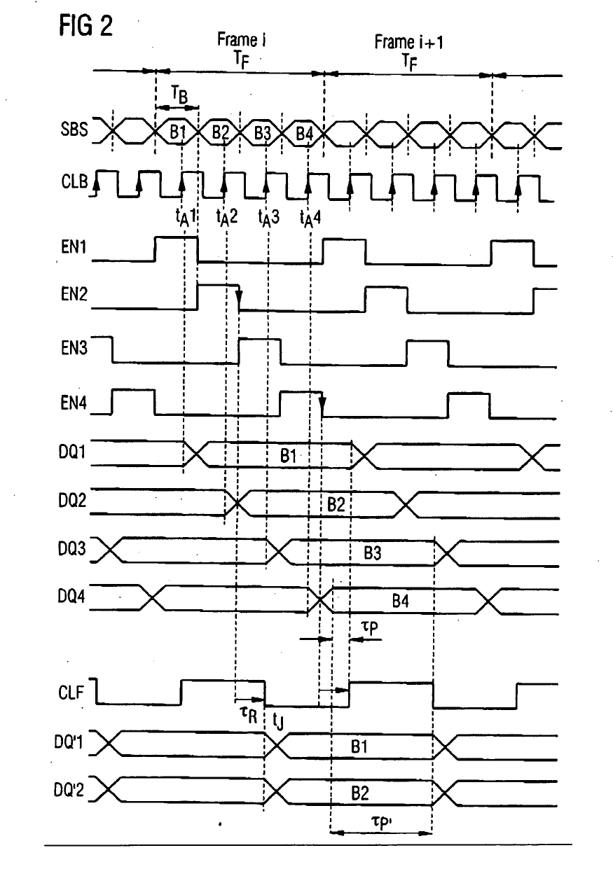

For the more detailed explanation of the operation of the demultiplexer 20, reference will be made to FIG. 2 which shows the variation of various signals over a common time axis, according to one embodiment of the invention.

The first (top) line in FIG. 2 shows the serial bit stream SBS as it appears at the data inputs D of all latch elements 22-1:4. The limits of the bit periods T_{B} are indicated by thin vertical dashed lines and the limits of the frames are indicated by bold vertical dashed lines. In the example discussed here, each frame contains n=4 successive bits which are designated by B1, B2, B3, B4 in accordance with their sequence in time. Each bit period has at its beginning and end in each case a transition time which is illustrated by inclined edges in the usual manner and in which the binary value of the relevant bit cannot be unambiguously acquired, that is to say is “uncertain”. Reliable sampling of the bits by means of the latch elements 22-1:4 may occur in a limited time window between these transition times, that is to say within a limited time window within the “validity period” of the bit.

In the second line, the input clock signal CLB is shown which is derived from the system clock signal CLS by the synchronizing circuit 10. This circuit 10 may generate the input clock signal CLB with such a phase that the active edges, following one another with the period T_{B}, of the input clock signal (in this case the rising edges) in each case appear at a time which remains within the validity period of a respective associated bit in every case, even if the phase of the serial bit stream shifts within certain tolerance limits, and also has a certain minimum distance both from the beginning and from the end of this validity period. Maintenance of these minimum distances may be necessary in view of the nature of the latch elements 22-1:4 because these elements may require a certain setup time τ_{S} before the clock edge and a certain holding time τ_{H} after the clock edge for their switching operation.

The appropriate setting of the relative phase between the input clock CLB and the serial bit stream SBS can be found during an initialization process via the phase locked loop 11 by incrementally changing the clock phase and monitoring the sampling quality. The steps of an initialization process by means of which other phase adjustments can also be carried out along the transmission link will be described at a later point. In FIG. 2, an adjustment is shown as example in which the times t_{A} of the active edges of the input clock signal are in each case located relatively shortly before the end of the validity period of the data bits so that the setup time τ_{S} and the holding time τ_{H} is just maintained.

As shown, the write control circuit 23 receives the input clock signal CLB and has n=4 outputs, each of which is allocated to the enable input EN of an individually allocated latch element of the group 22-1:4. The write control circuit 23 may supply via its four outputs the enable inputs EN of the latch elements 22-1:4 selectively one after the other at the rate of the input clock signal in each case with an enable pulse EN of a certain duration. These enable pulses are shown in the next four lines of FIG. 2 and numbered from EN1 to EN4 in accordance with their correlation with the latch elements 22-1:4.

The first bit of each frame, that is to say bit B1, may be sampled in the “first” latch element 22-1 and latched at its data output Q for the duration T_{F} of the frame period. For this purpose, the write control circuit 23 may apply the “first” enable pulse EN1 of each cycle to the element 22-1 with a duration which, at the latest, begins at time t_{A}1−τ_{S} and, at the earliest, ends at time t_{A}1+τ_{H}, t_{A}1 being the time of the active edge of the clock signal CLB for sampling the first bit B1. The beginning of the pulse EN1, however, may be later than time t_{A}1−T_{B}+τ_{H} and the end of the pulse may be earlier than time t_{A}1+T_{B}−τ_{S}. When all these conditions are met, it can be ensured that the latching process for bit B1 at data output Q of the latch element 22-1 begins at time t_{A}1.

In the example shown according to FIG. 2, the first enable pulse EN1 begins at the front bit boundary of the first bit B1 of a frame of the serial bit stream and ends with the rear bit boundary of this bit. Its duration is thus equal to T_{B}. The signal variation on the output line DQ1 of the latch element 22-1 is shown in the correspondingly designated line of FIG. 2. The bit B1 of the current frame Fi, appearing there, remains latched until the latching of the first bit of the next frame Fi+1 begins at time t_{A}1+T_{F}.

In the same manner as described above, the latching of the subsequent bits B2:4 of the current frame Fi in the latch elements 22-2:4 runs time-graded at intervals of in each case equal to T_{B} with time-graded enabling of these elements by the enabling pulses EN2:4. The signal variations on the output lines DQ2:4 of the latch elements are also shown in the correspondingly designated lines of FIG. 2.

The write control circuit 23 can contain a counter which is cyclically incremented with the frequency of the input clock signal CLB in each case over n=4 successive counts. The enabling pulse EN1 may be generated at the associated count output for the duration of the existence of the first count. The enabling pulse EN2 is generated for the duration of the existence of the second count at the associated count output, etc.

When the serial/parallel converter 20 is in normal operation, the cycles of the write control circuit 23 may be synchronized with the frames in such a manner that the first enabling pulse EN1 encounters the first bit of a frame of the serial bit stream SBS. This synchronization can be carried out by means of an initialization decoder 12 which is shown in FIG. 1 inside the input circuit 10. During an initialization phase, a training pattern may be sent by the data source 100, i.e. a serial bit stream from which a marking MRK can be decoded which uniquely identifies the last bit of a single frame. When this marking MRK is detected, the decoder 12 may bring the write control circuit 23 into a “zero state” so that the cyclically repetitive sequence of the enabling pulses EN1:n begins with the next input clock cycle following.

After valid latching of the last bit of each frame, that is to say bit B4 on line DQ4, the opportunity arises to sample all bits B1:4 simultaneously on the output lines DQ1:4 in order to forward them as 4-bit word in parallel format. This opportunity may exist during a time window τ_{P}, for as long as all n bits B1:4 of the respective same frame are simultaneously valid on the lines DQ1:4. In one embodiment of the invention, a sampling circuit (not shown) can be used for parallel sampling which responds to a frame clock signal which is derived from the input clock signal CLB and has active sampling edges within the time window τ_{P}.

The demultiplexer 20 shown in FIG. 1 has the advantage that the latency from the reception of the last bit of a frame to the parallel sampling of all bits of the relevant frame is extremely short. In conventional serial/parallel converters which operate with a cascade of a number of successive converter stages in a type of tree circuit, the latency is several times as long.

The abovementioned time window τ_{P} for the parallel sampling of the bits B1:4 on lines DQ1:4 is relatively narrow and becomes ever more narrow the higher the frequency f_{B} of the input clock is. The parallel sampling within this narrow window would require latch elements having extremely short setup and holding times; in addition, the latency would increase for the latest bit in each case.

In one embodiment of the invention, it is ensured by means of relatively simple measures that a wider time window is available for the parallel sampling and, nevertheless, the latency remains low. Generally said, this is achieved by relatching the k first bits B1:k (with 1≦k<n) from the output of the demultiplexer 20 within a circuit 30 at a time within a time interval which lies between the beginning of the validity of the k-th bit Bk and the end of the validity of the first bit B1. The bits B1:k then appear simultaneously at the outputs DQ′1:k of the latching circuit 31 from the said time, that is to say later than at the outputs DQ1:k of the demultiplexer 20, but with unchanged validity period. As a result, the time window for the parallel sampling of all n bits B1:n of one frame becomes much wider.

FIG. 1 shows a suitable circuit 30 for implementing this principle in conjunction with the demultiplexer 20, wherein k=n/2=2. The “first” k outputs of the demultiplexer, that is to say lines DQ1 and DQ2, lead to a block of latching elements 31 which receive at their clock input a frame clock signal CLF, the wave shape of which is shown in the correspondingly designated line of FIG. 2 and which may be generated by a frame clock generator 24. As shown, the frame clock signal CLF is a sequence of pulses, the repetition frequency of which is equal to f_{F} and the trailing edges (the falling edges in the case shown) in each case appear at a time t_{J} shortly after the k-th bit (that is to say the second) bit B2 of a frame on line DQ2 has become valid. The latching elements 31 may be clocked with these edges so that the k first bits B1:2 of a frame are latched on the output lines D′1:2 of the latching element 31 from time t_{J} until the (falling) trailing edge of the next frame clock pulse appears by means of which the first k bits of the next frame are latched at the outputs of the latching elements 31. The remaining bits B3:4 of the frame which appear on lines DQ3:4 are conducted unchanged through the circuit 30.

In the example shown, the (falling) trailing edges of the frame clock pulse are triggered by the trailing edge of the respective k-th enabling pulse EN2, they appear delayed by a short reaction time τ_{R} as shown in FIG. 2. The positioning time of the bits B1:2, which are thus “relatched”, on lines DQ′1:2 is shown in the lines directly below the frame clock signal CLF in FIG. 2. As can be easily seen, a time window σ_{P}′ which begins with the validity of the nth bit B4 of the frame on the line DQ4 is now available for the parallel sampling of all bits B1:4 of a frame. This time window ends with the end of validity of the (k+1)-th bit B3 on line DQ3. It is thus significantly longer than the time τ_{P}.

In the example shown, the (rising) leading edges of the frame clock pulse CLF are triggered by the trailing edge of the respective k-th enabling pulse ENk, that is to say by the trailing edges of the enabling pulses EN2, and also appear delayed by the reaction time τ_{R}. This advantageously results in the duty ratio of 1/2 for the frame clock pulses, i.e. the trailing edges appear a half frame clock period later than the rising edges. As shown as example in FIG. 1, an SR flip flop 24, the response time of which defines the abovementioned reaction time τ_{R}, can be used for generating this frame clock signal CLF. The set input S of flip flop 24 is triggered by the “falling” trailing edges of the respective nth enabling pulses EN4 and the reset input R of flip flop 24 is triggered by the (falling) trailing edges of the respective k-th enabling pulse EN2.

To provide a simple illustration of the exemplary case, a frame length of n=4 was described in the text above, and the number k=n/2 was selected for the number of “relatched” bits. In practice, e.g. if it is a matter of data transmission from or to storage modules, n will be much greater in most cases. The number k can also be greater or less than n/2. The advantage of the “relatching” described, namely the widened sampling window τ_{P}′ is obtained more or less with each number of 1≦k<n. The choice of k=n/2 is not mandatory but optimal. Naturally, such a choice is possible if n is an integral number which applies in most practical cases; otherwise the number (n+1)/2 or (n−1)/2 would be optimal for k.

Generally said, the k output lines DQ′1:k of the latch register 31 and the n-k output lines DQ(k+1):n of the demultiplexer 20 form a line group DF on which each frame in parallel format can be sampled within a relatively wide time window τ_{P}′. For this sampling, the edges, rising in the manner described above, of the frame clock pulse CLF can be used because these edges always appear within the said time window.

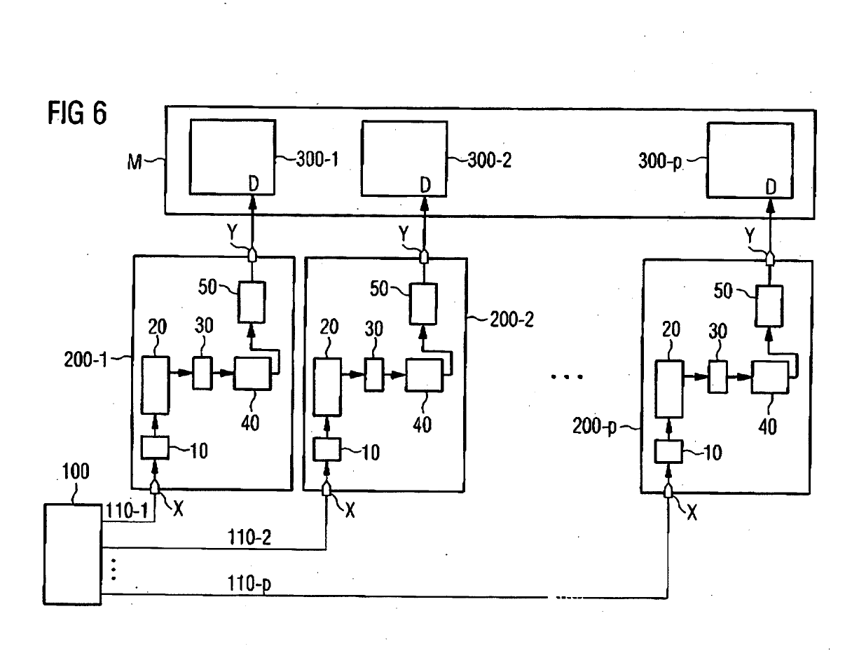

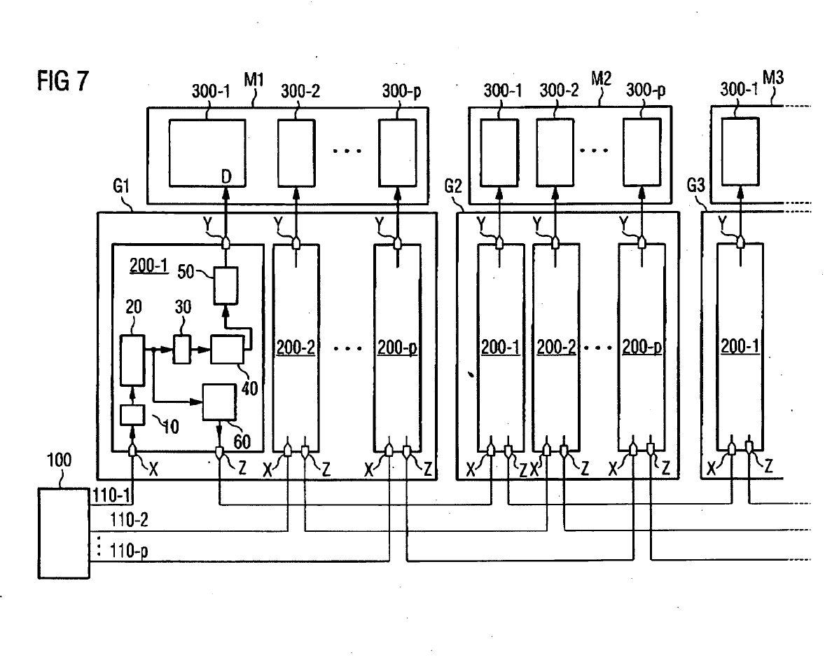

The reception of the frames at the data sink 300 may be clocked by a clock signal CLY which may be derived from the system clock signal CLS by a clock generator 310 according to FIG. 1. In the case where a number of data sinks are supplied in parallel with data in each case via an individually allocated transmission link (as will still be described later by means of FIGS. 6 and 7), the clock signal CLY is common to all data sinks.

In practice, the frame clock coming from the demultiplexer 20 may not be synchronous with the frame clocking of the associated data sink 300. That is to say, the phase of the “sink frame clock” CLY can shift with respect to the phase of the “demultiplexer frame clock” CLF in unpredictable manner. For this reason, it may be advantageous to provide between the line group DF and the data input of the data sink a buffer circuit which is drawn as block 40 in FIG. 1 and receives both clock signals CLF and CLY. This buffer circuit can contain a conventional FIFO register, the write pointer of which is controlled by the demultiplexer frame clock CLF and the read pointer of which is controlled by the sink frame clock CLY.

In an embodiment of the invention, the buffer circuit 40 contains a FIFO register which contains a multiplicity of q≧2 storage locations, each of which is designed for receiving the n data bits of a frame. A bypass bridges this FIFO register when the read pointer and the write pointer come close to one another. This allows the additional latency of the buffer circuit 40 in the data path to be reduced.

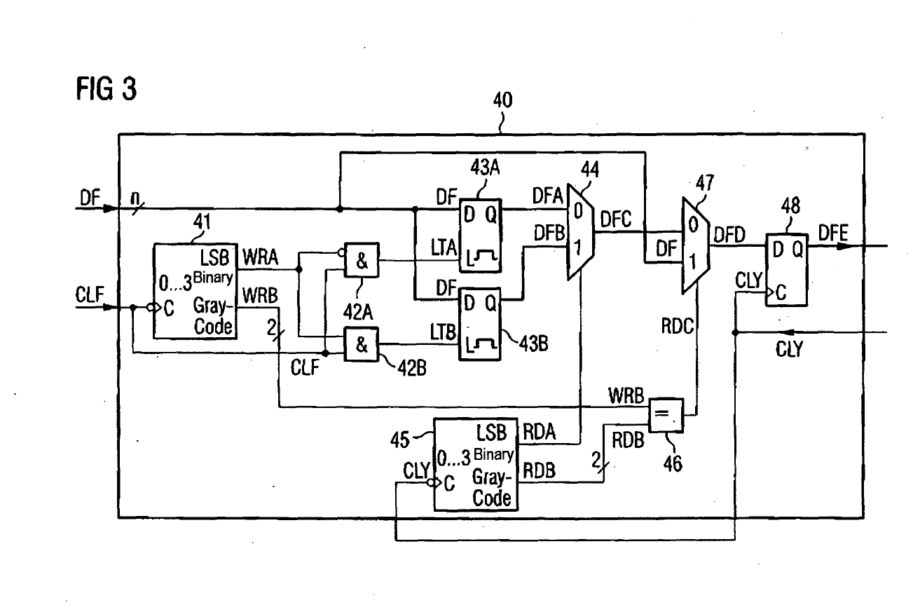

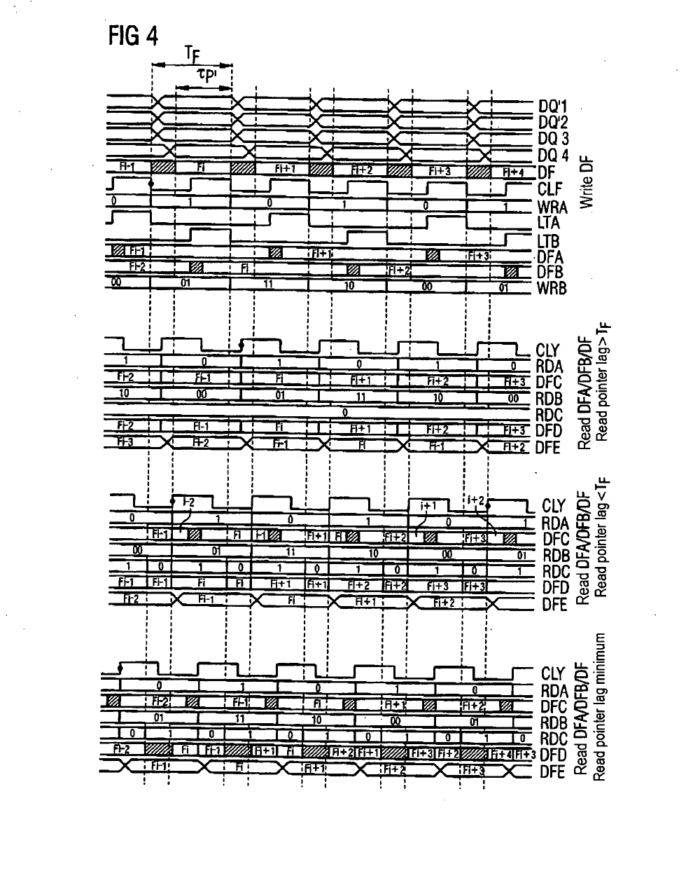

In an embodiment of the buffer circuit 40 which is shown in FIG. 3 and will be described as example in the text which follows, the FIFO register only contains q=2 storage locations. FIG. 4 shows in a diagram over a common time axis the signals and logic values which appear at various locations in the circuit during an operation of the buffer circuit 40, according to one embodiment of the invention. Some signals are drawn as wave shape with alternating “high” and “low” level. For the example described here, the agreement applies that the high level represents the logic value “1” and the low level represents the logic value “0”. Correspondingly, all binary signals in FIG. 4 are also shown as successive boxes with the bold inscription 0 or 1. In the description following, digits or numbers are in each case placed in “inverted commas” when they represent logic values or binary codes.

As shown, the diagram according to FIG. 4 is divided into four sections which are drawn one below the other over the same time axis. The first (top) section illustrates the write operation at the buffer circuit 40, the other sections illustrate the read operation for three different situations.

The four first lines of the top diagram section of FIG. 4 again shows the variation of the signals from the four outputs DQ′1, DQ′2, DQ3, DQ4 of the relatching circuit 30 (FIG. 1) and immediately below this, the sequence of frames Fi, Fi+1, . . . as shown as they are supplied in each case in parallel format as n-bit words via the line group DF coming from the relatching circuit 30. These frames are in each case valid within a time window of width τ_{P}′ (compare FIG. 2). The intermediate intervals in which parallel sampling of all n bits of a frame is not possible are symbolized by black areas. This DF frame sequence is received at the input of the buffer circuit 40 together with the frame clock pulses CLF which are generated by the frame clock generator 24 of the demultiplexer 20 (FIG. 1). These clock pulses CLF determine the “write clock” for the FIFO register contained in the buffer circuit 40. As has been described before, the (rising) leading edges of these pulses in each case appear during the validity time τ_{P}′ of a frame and are delayed by a half frame clock period with respect to the “falling” trailing edges.

As shown, the buffer circuit 40 contains a write counter 41 which is controlled by the write clock signal CLF at its clock input C. The write counter 41 counts cyclically over in each case 2q−1=4 counts from 0 to 3 and contains two count decoders (not shown), one for coding these counts in binary number code “00”, “01”, “10”, “11” and one for coding in Gray code “00”, “01”, “11”, “10”. At a first output, the counter 41 supplies a 1-bit signal WRA which only reproduces the least significant bit (LSB, that is to say bit 20) of the binary number code. At a second output, the counter 41 supplies a 2-bit signal WRB which reproduces the two bits of the Gray code in parallel format.

A special feature of the buffer circuit 40 according to FIG. 3 consists in that the write counter 41 is not clocked by the (rising) leading edges of the write clock CLF which fall into the validity times of the frames but by (falling) trailing edges, that is to say offset by a half frame period. In FIG. 4, the trailing edge of the write clock pulses CLF which sets the counter 41 to the “first” count “01” is marked by a black dot and the subsequent frame of the DF frame sequence is arbitrarily designated as frame F1.

As mentioned, the buffer circuit 40 contains two register stages 43A and 43B, each of which has an n-bit data input D for receiving the n-bit parallel words of the DF frame sequence and has a latch input L. Each of these register stages is of such a nature that it passes the data words received at the data input D to its data output Q as long as a latch signal received at the latch input is active, i.e. has the logic value “1”. As soon as the latch signal goes to its inactive logic value “0”, the currently received data word is latched for the duration of the active state of the latch signal at the data output Q.

The latch signal LTA for the register stage 43A are pulses which are generated in a gate 42A by AND combination of the inverted version of the output signal WRA of the write counter 41 with the frame clock signal CLF. The latch signal LTB for the register stage 43B are pulses which are generated in a gate 42B by AND combination of the output signal WRA of the write counter 41 with the frame clock signal CLF. The latch pulses LTA correspond to the pulses of the frame clock signal CLF which are allocated to the odd-numbered frames . . . Fi−1, Fi+1, Fi+3, . . . (“odd” frames), and the latch pulses LTB correspond to the pulses of the frame clock signal CLF which are allocated to the even-numbered frames . . . Fi−2, Fi, Fi+2, . . . (“even” frames). Thus, a frame sequence DFA which only contains the “odd” frames appears at the data output of register stage 43A and a frame sequence DFB which only contains the “even” frames appears at the data output of register stage 43B. The frame sequences DFA and DFB appear offset with respect to one another by one frame clock period T_{F} and the validity period of the frames in these frame sequences is in each case longer than T_{F} so that even and odd frames overlap in time.

The output signal WRA of the write counter 41, alternating between “0” and “1”, thus forms the write pointer for the two-stage register 43A, 43B via the AND gates 42A, 42B. To operate this register as a FIFO register, a first 2-to-1 multiplexer 44 is provided, the switching state of which is controlled by a read pointer RDA which is synchronized with the frame clock signal CLY of the data sink. Correspondingly, the clock signal CLY will also be called “read clock signal” in the text which follows. A read counter 45 is provided which is of the same configuration as the write counter 41 and is clocked by the rising edges of the read pulses CLY to count cyclically in each case from 0 to 3. The least significant bit of the binary number code of the count forms the read pointer RDA for controlling the multiplexer 44. At a logic value of “0” of the read counter RDA, the multiplexer 44 connects the DFA line group to its output and at a logic value of “1” of the read counter RDA, the multiplexer 44 connects the DFB line group to its output.

The FIFO multiplexer 44 thus supplies on its n-bit output line (line group DFC) a frame sequence DFC in which the individual frames . . . Fi, Fi+1, . . . appear in their original order but at the clock rate of the rising edges of the read clock signal CLY. This functions correctly as long as the read clock (rising edges of the read clock signal CLY) and the write clock (falling edges of the write clock signal CLF) are offset to one another by a minimum distance. Such a state, at which the rising edges of the read clock signal CLY and the falling edges of the write clock signal CLF are offset to one another by at least T_{F}/2 is illustrated in the lines of the second diagram section in FIG. 4.

If, however, the phases of write clock and read clock closely approach one another, a point is reached at which read/write operation is no longer possible. This point is defined by the transit time of the data from input DF of the buffer circuit 40 to the input D of the register 48 in relation to the phase relationship of the clock CLY. This transit time can be reduced further, and thus the latency of the buffer circuit 40 can be reduced further with the aid of a special measure. This measure consists in that a bypass is selectively switched in during certain intervals in order to temporarily bridge the FIFO register 43A, 43B in each case.

In the exemplary embodiment according to FIG. 3, the bypass consists of a connection of the line group DF at the input end to one input of a 2-to-1 multiplexer 47, the other input of which is connected to the output of the FIFO multiplexer 44. The bypass multiplexer 47 is controlled by a switching signal RDC which is generated by a comparator 46 which compares the Gray code WRB of the counts of the write counter 41 with the Gray code RDB of the count of the read counter. In the example shown, a comparator 46 for two-bit words is used, consisting of two exclusive-NOR gates (XNOR gates) and one AND gate. For the duration of a correspondence of WRB and RDB, the circuit 46 supplies a “1” by which the bypass multiplexer 47 is placed into a switching state in which it forwards the signals from line group DF to a line group DFD. During the intervals in which WRB and RDB differ, the output signal RDC of the comparator 46 assumes the logic value “0” by which the bypass multiplexer 47 is placed into a switching state in which it forwards the signals from the output of the FIFO multiplexer 44 to the line group DFD.

The third diagram section of FIG. 4 illustrates the situation for the exemplary case where the distance between write clock and read clock is less than T_{F} but, on the other hand, still large enough that the associated frame on the line group DFC is already valid with the rising edge of the read clock CLY. The diagram shows that switching the bypass multiplexer 47 (RDC from “1” to “0”) in the clock period before the rising edge of the read clock CLY does not lead to any change in state of the signals on the line group DFD.

Naturally, there is a minimum measure for the permissible distance between write clock and read clock. This minimum measure will be undershot as soon as the read clock comes so close to the write clock that it approaches the limit of the time window τ_{P}′ of the validity of the associated frame too much. The limit case in which the read clock just reaches the front boundary of the said time window is illustrated in the fourth diagram section of FIG. 4. To keep the latency of the buffer circuit as low as possible, the phase of the clock signal CLY determining the read clock should be set in such a manner that the read clock comes as close as possible to the front boundary of the said time window. This adjustment can be made during the initialization as will still be described below.

As shown, the n-bit output signal of the bypass multiplexer 47 appearing on the line group DFD is supplied to the data input of an n-bit latch circuit 48 which is clocked with the rising edges of the read clock signal CLY in order to supply the output frame sequence DFE of the buffer circuit 40. In this sequence, the frames appear in their original order and synchronized with the frame clock CLY provided by the data sink 300.

The “length” of the FIFO register, that is to say the number q of the successively selected register stages can also be greater than 2. Generally it holds true that the write counter and the read counter must cyclically counter over in each case 2q counting steps (that is to say from 0 to 2q−1) and that the write pointer and the read pointer, respectively, are decoded from the counts for the cyclic addressing of the q register stages. The FIFO multiplexer is correspondingly a q-to-1 multiplexer.

By itself, the buffer circuit described can synchronize the frame sequence supplied by the multiplexer 20 in the frame clock CLF with the frame clock CLY of the data sink 300 only if the phase difference between the edges of identical polarity of the two frame clock signals CLF and CLY is no more than one frame clock period T_{F}. This condition may be met in many cases.

However, it may occur that the phase difference between CLF and CLY is greater than T_{F}. Such a situation can occur, e.g. if the transmission link is operated in parallel with other transmission links in order to supply a number of data sinks from the data source 100. The transit times of the data to the various sinks can differ because of different distances from the data source by such an extent that a difference of more than one frame period exists between the longest transit time and the shortest transit time. This difference can be a number of frame periods at very high data rates.

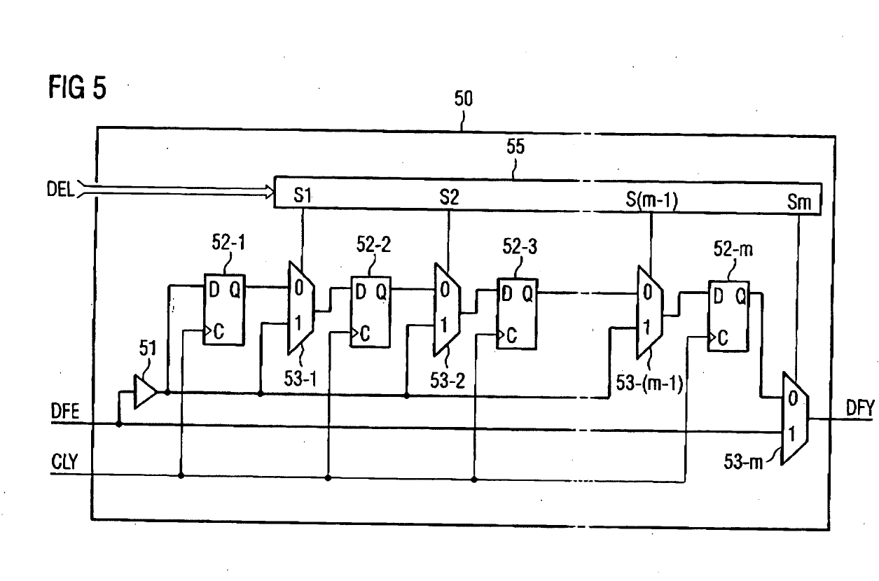

To equalize the said differences, an additional phase control may be carried out. In one embodiment of the invention, this may be achieved by a controllable delay circuit, the delay time of which can be varied in steps of in each case one whole frame period T_{F}. An exemplary embodiment of this is shown in FIG. 5.

In one embodiment, the delay circuit 50 according to FIG. 5 is inserted between the buffer circuit 40 and the associated data sink 300 but it can also be at another point within the transmission link. As shown the delay circuit 50 contains an m-link chain of delay elements 52-1, 52-2 . . . 52-m, where m is a natural number >0. In the example shown, each of the m delay elements 52-1:m is a register of n parallel D-type flip flops which transmits an n-bit data word present at its n-bit data input D to its Q output and latches it there when it is triggered at its clock input C by a rising clock edge. Each delay element 52-i is followed by a change-over switch (2-to-1 multiplexer) 53-i which is designed for transmitting n-bit data words and can be switched by an individually allocated binary switching signal (switching bit) Si. The logic value “0” or “1” of the switching bit Si determines whether the data word received at the 0 input or the data received at the 1 input of the associated change-over switch 53-i is passed through to the output.

The 0 input of each change-over switch 53-i is connected to the data output of the immediately preceding delay element 52-i. The 1-inputs of the m−1 first change-over switch 53-1 to 53-(m−1) receive the frame sequence DFE from the output of the buffer circuit 40 (see FIG. 3 and FIG. 4) via a common data amplifier 51. The I-input of the last change-over switch 53-m receives the frame sequence DFE directly.

The switching bits S(1:m) for the change-over switches 53-(1:m) are generated by a 1-of-m decoder 55 which receives a delay control signal in the form of a multi-bit code in order to specify whether all m switching bits should have the logic value “0” or which ones of the switching bits should have the logic value “1” (the other switching bits then remain at “0”). Thus, either none of the changeover switches or one selected change-over switch 53-i is placed into its 1-state.

In operation, the delay elements 52-(1:m) are triggered by the rising edges of the frame clock signal CLY. If all change-over switches 53-(1:m) are in the O-state, the chain of delay elements 52-(1:m) operates as m-stage shift register so that the frame sequence DFE at the input end appears at the output of the last change-over switch 53-m with a delay of m frame clock periods. The output sequence DFY is thus delayed by m*T_{F}+τ_{M} with respect to the input sequence DFE, where τ_{M} is the transit time for this change-over switch (multiplexer transfer time).

If only the first change-over switch 53-1 is in the I-state, the part-chain of the subsequent delay elements 52-(2:m) operates as (m−1)-stage shift register so that the delay is equal to (m−1)*T_{F}+τ_{M}. If only the last change-over switch 53-m is in the 1-state, the delay is only equal to τ_{M}. Generally it holds true that when i is the ordinal number of the change-over switch located in the 1-state, that is to say only the switching bit Si has the logic value “1”, the delay is (m−i)*T_{F}+τ_{M}.

FIG. 6 illustrates the case where the data source 100 simultaneously supplies a multiplicity of p serial bit streams which are sent with the same clock phase over p associated output lines 110-1, 110-2 . . . 110-p in order to be transmitted in each case as a sequence of n-bit words in parallel format to an associated data sink 300-1, 300-2, . . . 300-p, according to one embodiment of the invention. The p data sinks 300-(1:p) can be, e.g., DRAM memory chips which are combined in a module M, e.g. in a so-called DIMM (Double In-line Memory Module). Since the data sinks mandatorily have different spatial positions, their spatial distance to the data source is also different; similarly, the individual transmission paths can be exposed to different environmental influences. For this reason, individual buffering and transit time adaptation is necessary in each individual transmission path.

In the embodiment shown in FIG. 6, such “full buffering” of the module M is achieved in that a transmission link 200-i according to the invention as has been described above by means of FIG. 1 to FIG. 5 is inserted between each data link 110-i and the associated data sink 300-i. The components of each transmission link, that is to say the input circuit 10, the demultiplexer 20, the relatching circuit 30 (FIG. 1), furthermore the buffer circuit 40 (FIG. 3) and the delay circuit 50 (FIG. 5) are drawn in FIG. 6 as blocks within the respective transmission link 200-i, together with the connecting data lines (thin lines for serial bits, thick lines for n-bit parallel words). The existing connections and lines for clock and control signals are not shown in FIG. 6. All data sinks 300-1:p are operated with a common frame clock signal CLY which clocks the data reception at their data inputs and also determines the read clock in the buffer circuits 40 of all transmission links 200-1:p.

If the data sinks 300-(1:p) are individual memory chips (e.g. DRAMs) of a storage module (e.g. of a DIMM), the arrangement according to FIG. 6 results in a so-called “fully buffered” module which allows a write operation in which a data word of p*n bits in parallel format can be input with each memory clock. Such modules (fully buffered DIMMs, abbreviated FBDIMMs) are suitable, e.g., for implementing main memories in computers.

To increase the memory capacity, a number of similar memory modules can be provided which are connected in such a manner that each module can receive the data supplied by the data source (e.g. of a memory controller) 100 and accepts these data when it is individually addressed. FIG. 7 shows the arrangement of a combination of a number of modules M1, M3, . . . , each of which corresponds to the module M according to FIG. 6 and the p data sinks 300-1:p of which are allocated to the p output lines 110-1:p of the data source 100, according to one embodiment of the invention. Each data sink 300-i is associated with a transmission link 200-i which receives at its serial input X the associated serial bit stream and supplies at its parallel output Y the frames of this bit stream as n-bit words in parallel format.

As shown, each transmission link 200-i shown in FIG. 7 contains between its input X and its output Y the same circuits 10, 20, 30, 40, 50 as are also contained in each transmission link 200-i of the arrangement according to FIG. 6 and as has been described above by means of FIG. 1 to FIG. 5. The modules M1, M2, . . . and the in each case associated groups G1, G2, . . . of the transmission links 200-1:p are arranged at different distances from the data source 100; they thus form a “row” graded in accordance with distance.

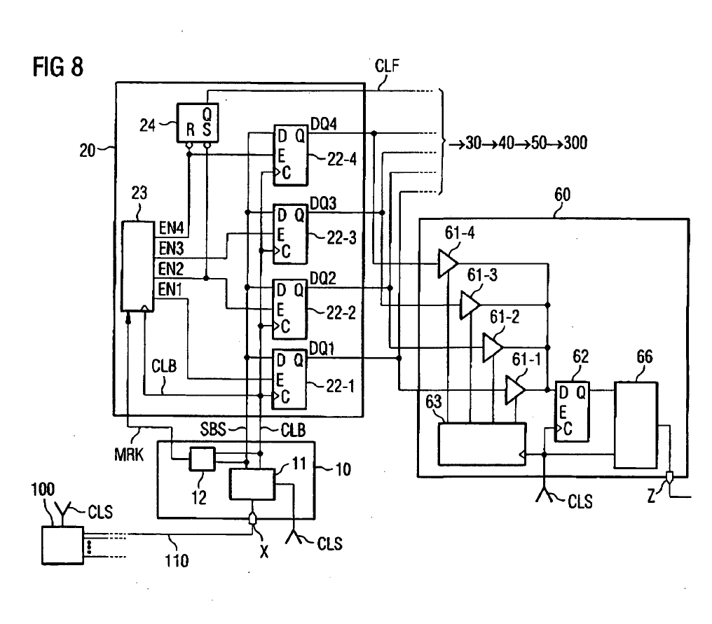

The p transmission links of the “first” group G1 which has the shortest distance to the data source 100 receive at their inputs X the serial bit streams directly from the output lines 110-1:p of the data source 100. In the following groups G2, G3, . . . , each transmission link 200-i receives at its input X the associated serial bit stream, not directly from the associated data line 110-i but via a loop which runs through a part of the i-th transmission link 200-i of the respective preceding group. This loop regenerates the serial bit stream received at the input X and leads through the demultiplexer 20 and from there via a regenerating circuit 60 to a serial output Z of the relevant transmission link. The configuration and the operation of the regenerating loop will be described by means of FIG. 8 in the text which follows.

FIG. 8 shows the details of the regenerating circuit 60 in conjunction with the demultiplexer 20, the configuration and operation of which has already been described above by means of FIG. 1, according to one embodiment of the invention. As shown, the regenerating circuit 60 has n=4 inputs which are connected to the n outputs DQ1:4 of the demultiplexer 20 and can be selectively connected to the data input D of a D-type flip flop 62 via in each case one associated switch. In an embodiment, the said n switches 61-1:4 are switchable data drivers and are cyclically switched on by a read control circuit 63.

As shown, the switches 61-1:4, the read control circuit 63 and the flip flop 62 together form an n-to-I multiplexer. The read control circuit 63 is clocked by the active (e.g. rising) edges of a read clock signal, e.g. the system clock signal CLS which is also supplied to the clock input C of the flip flop 62. On average, this read clock signal has the same frequency f_{B} as the input clock signal CLB of the demultiplexer 20 but its phase can differ from the phase of the clock signal CLB.

That active edge of the read clock signal CLS which appears at the demultiplexer output DQ1 during the validity of the first bit B1 of a frame (compare FIG. 2) sets the read control circuit 63 in such a manner that the switch 61-1 is closed and the relevant bit passes to the data input D of the flip flop 62. In response to the subsequent three active edges of the signal CLS, the read control circuit 63 successively closes the switches 61-2, 61-3, 61-4 in order to conduct bits B2, B3, B4 to the flip flop 62. Similar to the write control circuit 23, the read control circuit 63 can be constructed as counter which in each case counts cyclically over n−4 counts.

As shown, the bit sequence appearing at output Q of the flip flop 62 is supplied to a data transmitter 66 which samples the individual bits with the clock signal and supplies them as “regenerated” serial bit stream to the output Y.

The demultiplexer 20 thus fulfils a dual function in this case. On the one hand, it provides for the serial/parallel conversion in the transmission link leading from input X to the parallel output Y. On the other hand, it simultaneously, together with the regenerating circuit 60, operates as FIFO circuit wherein the latch elements 22-1:4 of the demultiplexer 22 form an n-stage FIFO register, the write pointer of which is formed by the n output signals EN1:4 of the write control circuit 23 and the read pointer of which is formed by the n output signals of the read control circuit 63. By means of this FIFO circuit in each transmission link, the phase of the serial bit stream forwarded via the loop is in each case aligned with the phase of the clock signal CLS.

In the arrangement according to FIG. 7, all transmission links 200-1:p of each group G1, G2, . . . , with the exception of the last group (not shown), contain the loop going via an associated regenerating circuit 60 in order to conduct the serial bit streams of a group, coming from the data source 100, to the next group. A suitable basic setting of the phases of the write and read clocks in the FIFO circuits of each transmission link and a suitable setting of the delay devices 50 in each transmission link ensures that the frame sequences of all serial bit streams in each case arrive as sequences of serial/parallel-converted n-bit data words at their destination data sinks in registration in time so that all sinks can be operated in synchronism.

The basic settings mentioned can be carried out during an initialization process before each activation (and, if desired, also in intervals between operating sections). In the text which follows, an example of a method for carrying out the settings is described.

Firstly, the data source 100 is caused to send the training pattern mentioned above. This pattern can consist, e.g. of n successive n-bit code words, wherein the second to nth code words are identical to one another but different from the first code word. For the exemplary case of n=12, the pattern can be arranged as follows:

| | | | |
|---|---|---|---|
| first code word | 0111 | 1111 | 1101 |
| eleven following code words | 0101 | 0101 | 0101 |

wherein the sequence in time of the bits must be read from left to right. From the training pattern, the marking MRK which synchronizes the demultiplexer with the frame boundaries as has been described above in conjunction with FIG. 1 is derived within each transmission link in the decoder of the demultiplexer.

In a second step the uncertainty, moving within one frame period, of the initial state of the buffer circuit in each transmission link 200-i must be eliminated. For this purpose, measures are taken in order to be able to modify the phase of the common frame clock CLY of all data sinks. As shown in FIG. 1, this is made possible by a phase control element 311 at the output of the CLY clock generator 310. In each transmission link 200-i between the data source 100 and a data sink 300-i, the clock signal CLF which forms the write clock signal CLF for the buffer circuit 40 is first brought into registration with the common clock signal CLY. For this purpose, the phase of the common clock signal CLY is changed by means of the control element 311 in a number of steps up to a measure of 360° at the maximum, wherein the phase of the CLF clock edges can be measured in comparison with the CLY clock edges in each transmission link 200-i in order to find the point of phase registration. Using this information, the read pointers of the buffer circuits can be initialized deterministically.

After these initialization steps, two accurate information items are available: firstly an accurate information item about the relative phase angle between the common sink frame clock CLY and the frame clock CLF which determines the write clock of the buffer circuit 40 in the associated transmission link 200-i; secondly an accurate information item about the number of frame periods by which the serial/parallel-converted frames must be individually delayed in each transmission link so that the data arrive in clock synchronism at all sinks. It is thus also known which transmission link is the “latest one”, i.e. in which transmission link the shortest delay must be set.

Correspondingly, a third initialization step follows in which the phase of the common clock signal CLY is set in such a manner that the transit time or latency of the data via the buffer circuit 40 of the “latest” transmission link is minimized. This means that the distance between write pointer and read pointer in this buffer circuit has the just permissible minimum measure. Selection of the “latest” transmission link as reference for this setting ensures that any possible drift of the write clock signal CLF of the transmission link with respect to the common clock signal CLY can be compensated for. The other transmission links may be initialized by setting the delay device 50 in accordance with the previously measured phase differences.

The transit time or latency of the data from the source 100 to all data sinks is thus minimized to the transmit time of the data passing via the “latest” transmission link which, in turn, is minimized to the minimum permissible measure.

In principle, the transmission link necessarily contains a serial/parallel converter which converts the serial bit stream into the serial/parallel converted n-bit words. Each of these data words should reproduce a certain frame of the serial bit stream, i.e. a certain section, consisting of n successive bits, of the serial bit stream. In order to keep the latency of the entire transmission link low, the latency of the demultiplexer should also be as low as possible.

A serial/parallel converter may therefore contain the following: A 1-to-n demultiplexer which is constructed and controllable in such a manner that the successive data bits of the serial bit stream (SBS) appear in succession at intervals equal to a bit period T_{B} of the serial bit stream cyclically at n data outputs and remain latched at the respective data output until a data bit appears again at the relevant data output. A relatching circuit with latching elements which receive the signals from the data outputs of the demultiplexer at which the first k data bits of each cycle appear and which are enabled in each case at a time which is between the beginning of the latching of the last data bit and the end of the latching of the first data bit of the relevant cycle in the demultiplexer, wherein 1≦k<n.

Such a serial/parallel converter has the advantage that its latency is extremely short. At the n parallel data outputs of the 1-to-n demultiplexer, the n data bits of each n-bit data word appear staggered in time at intervals of in each case one bit period T_{B} and in each case for the duration of n bit periods. The first bit of each data word appears virtually immediately after its reception and the nth (that is to say last) bit appears already n−1 bit periods later. Due to the relatching circuit according to the invention, the time window within which all n bits can be sampled in parallel is noticeably enlarged.

Further a buffer circuit and an additional adjustable delay circuit for synchronizing the serial/parallel converted frames with the clock operation of the data sink may be provided. Moreover a number of transmission links for the synchronized transmission of a number of serial bit streams as sequences of serial/parallel converted frames to a number of data sinks operated in parallel, e.g. to the individual DRAM chips of storage modules may be combined. All these embodiments are characterized by the fact that their contribution to the latency of the data transmission is small.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

What is claimed is:

1. A device for processing binary data, comprising:
at least one transmission link having an input for receiving a serial bit stream and an output for forwarding bits in a parallel format, the at least one transmission link comprising:
a serial/parallel converter which converts n≧2 successive data bits of the serial bit stream to n-bit data words in the parallel format, the serial/parallel converter comprising:
a 1-to-n demultiplexer having n data outputs, wherein each of the successive data bits of the serial bit stream of a respective cycle are latched and appear in succession at intervals equal to a bit period T_{B} cyclically at a respective data output and remain latched at the respective data output until a data bit of a subsequent cycle appears at the respective data output; and
a relatching circuit with latching elements which receive signals only from data outputs of the demultiplexer at which the first k successive data bits of a respective cycle appear and which are enabled at a time which is between the beginning of a latching of a last data bit of the successive data bits and the end of a latching of a first data bit of the successive data bits for a respective cycle in the demultiplexer, wherein 1≦k<n.

2. The device as claimed in claim 1, wherein k is equal to at least one of n/2, (n+1)/2, and (n−1)/2.

3. The device as claimed in claim 1,
wherein the demultiplexer contains a group of n latch elements, each of which has a data input for receiving the serial bit stream, a clock input for receiving an input clock signal, an enable input for receiving a respective enable pulse, and a data output, wherein each of the n latch elements latch at the data output a data bit present at the data input when an active edge of the input clock signal and the respective enable pulse is simultaneously present,
wherein the demultiplexer is associated with an input circuit which applies to the demultiplexer the input clock signal and the serial bit stream in such a time relationship that the active edges of the input clock signal, following one another with the bit period T_{B}, appear at a time t_{A} which is within the validity period of an associated bit of the serial bit stream and, from the beginning of this period, has a time interval at least equal to the setup time τ_{S} of the latch element and, from the end of said period, has a time interval at least equal to the holding time τ_{H} of the latch elements, and
wherein the demultiplexer comprises a write control circuit which selects the latch elements cyclically in a preselected order at a rate of the input clock signal in order to apply, to the enable input of the element selected, an enable pulse, the duration of which is within the limits of the data bit present in each case and covers at least the time window extending from t_{A}−τ_{S} to t_{A}+τ_{H}.

4. The device as claimed in claim 3,
wherein the demultiplexer is associated with a frame clock generator which derives, from the input clock signal, a first frame clock signal as a sequence of pulses, having a repetition period equal to n*T_{B}, and leading edges of which are triggered by trailing edges of the enable pulses of the write control cycles and trailing edges of which are triggered by trailing edges of the enable pulses of the write control cycles,
wherein the latching elements of the relatching circuit are enabled by the leading edges of the pulses of the first frame clock signal in order to latch the signals from the data outputs of the latch elements of the demultiplexer which receive a first k enable pulses of each write control cycle, and
wherein the relatching circuit passes signals from data outputs of remaining n−k latch elements unchanged.

5. The device as claimed in claim 4,
wherein the transmission link comprises a buffer circuit which receives, at an input, the signals latched by the relatching circuit and, under control by the first frame clock signal, writes them into a FIFO register which, under control by a second frame clock signal is read out, and
wherein the second frame clock signal is also the clock signal for the clock control of the data reception at a data sink.

6. The device as claimed in claim 5,
wherein the FIFO register of the buffer circuit contains q≧2 storage locations, each of which is designed for accepting n data bits of a frame,
wherein a write control circuit in the buffer circuit contains a write counter which is clocked by the trailing edges of the pulses of the first frame clock signal in order to count cyclically from 0 to 2q−1, and which, at a first output, generates a write pointer, decoded from the count, for the storage locations of the FIFO register and generates a Gray code of the counts at a second output,
wherein a read control circuit in the buffer circuit contains a read counter which is clocked by the leading edges of the pulses of the second frame clock signal in order to count cyclically from 0 to 2q−1 and which generates at a first output a read pointer, decoded from the count, for the storage locations of the FIFO register and generates a Gray code of the counts at a second output, and
wherein the buffer circuit also contains a bypass multiplexer which is controlled by a comparator circuit receiving the counts of the write counter and of the read counter in order to pass the data read out of the FIFO register for times of non correspondence of both counts and pass the signals received at the input of the buffer circuit for times of correspondence of the two counts.

7. The device as claimed in claim 6, wherein the comparator circuit receives the Gray codes of the counts of the write counter and of the read counter.

8. The device as claimed in claim 7, wherein a logic function of the comparator circuit is an exclusive OR function.

9. The device as claimed in claim 6,
wherein the number q of the storage locations of the FIFO register is equal to 2, and
wherein the write pointer for the storage locations of the FIFO register is the least significant bit of the binary number code of the count of the write counter.

10. The device as claimed in claim 1, wherein on a data path of the transmission link, a delay device is additionally inserted, the delay time of which can be varied in increments of in each case one frame period T_{F}.

11. The device as claimed in claim 1,
wherein a number of transmission links is ≧2,
wherein each transmission link is arranged between an individually allocated output of a data source and an individually allocated data sink, and
wherein the clock signal for the clock control of the data reception at all data sinks is a common clock signal.

12. The device as claimed in claim 11,
wherein the transmission links are divided into at least two groups of in each case p≧1 transmission links, wherein the groups form a row and all transmission links, with the exception of the transmission links of the last group of the row, additionally contain a regenerating circuit which generates from the output signals of the demultiplexer, and delivers to a serial output, a regenerated version of the serial bit stream received at the input of the relevant transmission link,
wherein the input of each transmission link of the first group of the row is connected to an individually allocated output of the data source, and
wherein the input of each transmission link in the subsequent groups of the row is connected to the serial output of an in each case individually allocated transmission link of the respective preceding group of the row.

13. The device as claimed in claim 12, wherein the regenerating circuit contains an n-to-1 multiplexer which is controlled by active edges of a read clock signal of frequency f_{B}.

14. The device as claimed in claim 5, wherein a control element for changing the phase of the second frame clock signal is provided.

15. A device for processing binary data, comprising:
at least one transmission link, the transmission link comprising:
a serial/parallel converter converting n≧2 successive data bits of a serial bit stream as n-bit data words in a parallel format as frames; and
a buffer circuit comprising:
a FIFO register and receiving at its input the frames of the serial/parallel converter, wherein a write pointer of the buffer circuit is controlled by a first frame clock and a read pointer of the buffer circuit is controlled by a second frame clock, and wherein the FIFO register is bridged by a bypass when the read pointer and the write pointer come close to one another.

16. The device as claimed in claim 15,
wherein the FIFO register of the buffer circuit contains q≧2 storage locations, each of which is designed for accepting n data bits of a frame,
wherein a write control circuit in the buffer circuit contains a write counter which is clocked by trailing edges of pulses of the first frame clock signal in order to count cyclically from 0 to 2q−1, and which, at a first output, generates the write pointer, decoded from the count, for the storage locations of the FIFO register and generates a Gray code of the counts at a second output,
wherein a read control circuit in the buffer circuit contains a read counter which is clocked by leading edges of the pulses of the second frame clock signal in order to count cyclically from 0 to 2q−1 and which generates at a first output a read pointer, decoded from the count, for the storage locations of the FIFO register and generates a Gray code of the counts at a second output, and
wherein the bypass of the buffer circuit is a bypass multiplexer which is controlled by a comparator circuit receiving the counts of the write counter and of the read counter in order to pass the data read out of the FIFO register for times of non correspondence of both counts and pass the signals received at the input of the buffer circuit for times of correspondence of the two counts.

17. The device as claimed in claim 16, wherein the comparator circuit receives the Gray codes of the counts of the write counter and of the read counter.

18. The device as claimed in claim 17, wherein a logic function of the comparator circuit is an exclusive OR function.

19. The device as claimed in claim 16,
wherein the number q of the storage locations of the FIFO register is equal to 2, and
wherein the write pointer for the storage locations of the FIFO register is the least significant bit of the binary number code of the count of the write counter.

20. The device as claimed in claim 15, wherein a control element for changing the phase of the second frame clock signal is provided.

21. A device for processing binary data, comprising:
at least one transmission link having an input for receiving a serial bit stream and an output for forwarding bits in a parallel format; and
a serial/parallel converter converting n≧2 successive data bits of a serial bit stream as n-bit data words in the parallel format as frames, wherein the transmission link further comprises a delay device, the delay time of which can be varied in increments of in each case one frame period T_{F}.

22. A device for processing binary data, comprising:
at least two transmission links, each transmission link comprising:
an input for receiving a serial bit stream and an output for forwarding bits in a parallel format; and
a serial/parallel converter converting n≧2 successive data bits of a serial bit stream as n-bit data words in a parallel format as frames, wherein each transmission link is arranged between an individually allocated output of a data source and an individually allocated data sink, and wherein a clock signal for a clock control of the data reception at all data sinks is a common clock signal.

23. The device as claimed in claim 22,
wherein the transmission links are divided into at least two groups of in each case p≧1 transmission links, wherein the groups form a row and all transmission links, with the exception of the transmission links of the last group of the row, additionally contain a regenerating circuit which generates from the output signals of a demultiplexer, and delivers to a serial output, a regenerated version of the serial bit stream received at the input of the relevant transmission link,
wherein the input of each transmission link of the first group of the row is connected to an individually allocated output of the data source, and
wherein the input of each transmission link in the subsequent groups of the row is connected to the serial output of an in each case individually allocated transmission link of the respective preceding group of the row.

24. The device as claimed in claim 23, wherein the regenerating circuit contains an n-to-1 multiplexer which is controlled by active edges of a read clock signal of frequency f_{B}.
